(19) United States
(12) Patent Application Publication
(10) Pub. No.: US 2019/0360090 A1
(43) Pub. Date: Nov. 28, 2019

(54) CYLINDRICAL SPUTTERING TARGET AND METHOD FOR PRODUCING SAME

(71) Applicant: JX Nippon Mining & Metals Corporation, Tokyo (JP)

(72) Inventors: Yoshitaka Tsuruta, Ibaraki (JP); Tomoya Negishi, Ibaraki (JP)

(21) Appl. No.: 16/484,144

(22) PCT Filed: Mar. 1, 2018
(86) PCT No.: PCT/JP2018/007865

§ 371 Date: Aug. 7, 2019

(30) Foreign Application Priority Data
Mar. 31, 2017 (JP) 2017-072169

(51) Int. Cl. C23C 14/34; C04B 35/453; H01J 37/34

(52) U.S. Cl. CPC C23C 14/3407; C04B 2235/604; H01J 37/3491; C04B 35/453

(57) ABSTRACT

A cylindrical sputtering target according to the present invention comprises: a metallic cylindrical substrate; and a ceramic cylindrical target material joined to an outer peripheral side of the cylindrical substrate and integrally formed so as to have a length of 750 mm or more in an axial direction, wherein a variation coefficient of a bulk resistivity in an axial direction is 0.05 or less on the outer peripheral surface of the cylindrical target material.

### TECHNICAL FIELD

The present invention relates to a cylindrical sputtering target including a metal cylindrical substrate and a ceramic cylindrical target material integrally formed so as to have an axial length of 750 mm or more on an outer peripheral side of the cylindrical substrate, and to a method for producing the same. More particularly, the present invention proposes a technique capable of achieving uniform target characteristics in an axial direction by suppressing curving or bending that may occur when forming a long cylindrical target material.

### BACKGROUND ART

For example, in sputtering for forming a transparent conductive thin film made of ITO, IZO or the like in the production of organic ELs, liquid crystal displays, touch panels or other display devices, magnetron sputtering has been manly carried out using a flat sputtering target produced by joining a flat target material onto a flat substrate such as a disc. In addition, rotary sputtering has come into practical use. The rotary sputtering is carried out by rotating a cylindrical sputtering target produced by joining a cylindrical target material onto an outer peripheral surface of a cylindrical substrate, around an axis.

Recently, as dimensions of displays or the like have been decreased, the cylindrical sputtering target for sputtering a thin film has also been required to have a larger length in an axial direction.

However, if the ceramic cylindrical target material produced by subjecting raw material powder to cold isostatic pressing followed by heating and sintering has a longer length in the axial direction of 750 mm or more, various problems are caused during the production accordingly. Therefore, it is not easy to lengthen the cylindrical sputtering target.

Techniques for addressing such types of problems are disclosed in Patent Documents 1 and 2.

Patent Document 1 discloses that granules are prepared from a slurry containing ceramic raw material powder and an organic additive prior to CIP forming, and an amount of an organic additive is from 0.1 to 1.2% by mass relative to an amount of the ceramic raw material powder, for the purpose of providing a high-density and long ceramic cylindrical sputtering target material.

Patent Document 2 proposes a method for filling ceramic powder in a forming mold having a circular pillar shaped mandrel and a cylindrical mold flask and performing cold isostatic pressing in order to render a circumferential thickness of the ceramic cylindrical formed body uniform, in which the ceramic powder is filled in the forming mold while rotating the forming mold around a central axis of the circular pillar shaped mandrel, and the ceramic powder is filled in the forming mold using a fixed funnel above the forming mold.

### CITATION LIST

### Patent Literatures

Patent Document 1: Japanese Patent Application Publication No. 2013-147368 A

Patent Document 2: Japanese Patent Application Publication No. 2012-139842 A

### SUMMARY OF INVENTION

### Technical Problem

When producing the cylindrical target material of the long cylindrical sputtering target as described above, the forming of the cylindrical formed body by means of cold isostatic press (also called CIP) generates curving that bends like a bow in the axial direction. Such curving substantially disappears in view of appearance by smoothing an outer surface of a cylindrical sintered body obtained by heating and sintering the cylindrical formed body when grinding the cylindrical sintered body. Conventionally, this has not been regarded to be problematic.

Here, conventionally, in view of a grinding amount of the cylindrical sintered body for eliminating such curving, dimensions of the cylindrical formed body or cylindrical sintered body have been set such that a thickness of the cylindrical sintered body is larger than a predetermined product thickness in a radial direction.

However, when the thicker cylindrical formed body is sintered, a difference in density or resistance in the thickness direction becomes remarkable due to a difference in temperature history between a surface side and a central side in the thickness direction. After sintering, the grinding of the cylindrical sintered body having curving as described above such that the curving disappears increases the grinding amount on the end side in the axial direction where the influence of the curving greatly appears, so that a part close to the center in the thickness direction is exposed as a surface. Therefore, in the cylindrical target material to be produced, the resistance characteristics are different between the end side and the center side in the axial direction. As a result, particularly the long cylindrical sputtering target causes a problem that the non-uniform resistance characteristic in the axial direction leads to generation of nodules and particles, and results in a difference in resistance of a formed film.

An object of the present invention is to solve such problems of the conventional cylindrical sputtering targets. The object is to provide a cylindrical sputtering target that can suppress curving of a cylindrical formed body for forming a long cylindrical target material and can achieve uniform resistance characteristics in the axial direction, and a method for producing the same.

### Solution to Problem

As a result of intensive studies, the present inventors have revealed that the curving of the cylindrical formed body is caused by filling irregularity of the raw material powder when filling a forming mold with raw material powder before cold isostatic pressing, and by, due to the filing irregularity, uneven action of force of a press during the cold isostatic pressing, and have found that by improving them, the curving of the cylindrical formed body obtained by the cold isostatic pressing can be suppressed. Based on the findings, the present inventors have considered that the grinding amount of the cylindrical sintered body can be made uniform in the axial direction, and a varying amount of the resistance characteristic can be suppressed to a lower level at the end side and the central side in the axial direction of the cylindrical target material.

Based on the findings, a cylindrical sputtering target according to the present invention comprises: a metallic cylindrical substrate; and a ceramic cylindrical target material joined to an outer peripheral side of the cylindrical substrate and integrally formed so as to have a length of 750 mm or more in an axial direction, wherein a variation coefficient of a bulk resistivity in an axial direction is 0.05 or less on an outer peripheral surface of the cylindrical target material.

In the cylindrical sputtering target according to the present invention, it is preferable that the cylindrical target material has a relative density of 99.0% or more relative to theoretical density.

Here, in the cylindrical sputtering target according to the present invention, it is preferable that the cylindrical target material is ITO, IZO or IGZO.

In cylindrical sputtering target according to the present, the cylindrical substrate and the cylindrical target material can be joined by a brazing material having a melting point of 200° C. or less.

The method for producing the cylindrical sputtering target according to the present invention is a method for producing a cylindrical sputtering target comprising a metallic cylindrical substrate and a ceramic cylindrical target material joined to an outer peripheral side of the cylindrical substrate and integrally formed so as to have an axial length of 750 mm or more, the method comprising: a powder filling step of filling a cylindrical forming space in a forming mold with raw material powder; a forming step, after the powder filling step, of subjecting the raw material powder in the forming space to cold isostatic pressing to form a cylindrical formed body; and a sintering step, after the forming step, of sintering the cylindrical formed body by heating to provide a cylindrical sintered body, wherein the powder filling step comprises providing tapping vibrations in an up-down direction for dropping down the forming mold to abut against a disposed surface with the forming mold, while an opening portion on an upper end side of the forming space is provided with a sieve so as to cover the opening portion and the raw material powder is filled in the forming space through the sieve, and the raw material powder is filled in the forming space while carrying out at least five tapping vibrations per 1 kg of an amount of the raw material powder filled; and wherein the forming step comprises performing the cold isostatic pressing while disposing a reinforcing member for supporting the forming mold from its outer peripheral side.

In addition, in the method for producing the cylindrical sputtering target according to the present invention, the cylindrical formed body has a curving amount of 1 mm or less.

Further, in the method for producing the cylindrical sputtering target according to the present invention, the cylindrical formed body has a curving amount of 4 mm or less.

### Advantageous Effects of Invention

According to the present invention, the filling irregularity of the raw material powder in the forming mold can be suppressed during the production, and the curving of the cylindrical formed body obtained by cold isostatic pressing can be prevented from being generated. As a result, the cylindrical sintered body can be uniformly ground in the axial direction, so that uniform resistance characteristics in the axial direction of the cylindrical sputtering target can be achieved.

### BRIEF DESCRIPTION OF DRAWINGS

FIG. 1 is a longitudinal sectional view including a central axis, which shows a forming mold that can be used in a method for producing a cylindrical sputtering target according to an embodiment of the present invention.

### DESCRIPTION OF THE PREFERRED EMBODIMENTS

Hereinafter, embodiments of the present invention will be described in detail.

A cylindrical sputtering target according to one embodiment of the present invention includes: a metallic cylindrical substrate; and a ceramic cylindrical target material joined an outer peripheral side of the cylindrical substrate via a certain brazing material and integrally formed so as to have a length of 750 mm or more in an axial direction, wherein a variation coefficient of a bulk resistivity in the axial direction is 0.05 or less on the outer peripheral surface of the cylindrical target material.

### (Composition)

The cylindrical target material is made of ceramics, and more specifically, it is made of, for example, ITO, IZO or IGZO.

When the cylindrical target material is made of ITO, it contains indium (In), tin (Sn) and oxygen (O), and has an atomic concentration (at %) ratio Sn/(In+Sn) of, for example, from 0.02 to 0.40. Typically, the ratio Sn/(In+Sn) is from 0.02 to 0.15.

When the cylindrical target material is IZO, it contains indium (In), zinc (Zn) and oxygen (O), and has an atomic concentration (at %) ratio Zn/(In+Zn) of, for example, from 0.05 to 0.25.

When the cylindrical target material is made of IGZO, it contains indium (In), gallium (Ga), zinc (Zn), oxygen (O), and has an atomic concentration (at %) ratio of, for example, 0.30 In/(In+Ga+Zn)≤0.36, 0.30≤Ga/(In+Ga+Zn)≤0.36, 0.30≤Zn/(In+Ga+Zn)≤0.36.

The ceramic cylindrical target material as described above may contain at least one of Fe, Al, Cr, Cu, Ni, Pb, and Si as other elements. In this case, the total content of these elements is preferably 100 ppm by mass or less. If the contents of these elements are too high, there is a concern that film properties may be degraded.

The contents of Zn, In and the like described above can be appropriately changed in accordance with conductivity and the like of a thin film of interest.

The contents of In, Zn, and the like can be measured by X-ray fluorescence analysis (XRF).

### (Length in Axial Direction)

The cylindrical target material has a length of 750 mm or more in an axial direction, and is integrally formed along the full length in the axial direction. In the long cylindrical sputtering target provided with such a cylindrical target material, there is a need for forming a thin film on a display that is increasing its size in recent years, whereas such a long ceramic target material is prone to curving during forming, so it is difficult to produce it as an integrated product. In other words, a cylindrical target material having a length of less than 750 mm in the axial direction does not increase the curving during forming to such extent that a variation in resistance characteristics due to a difference in a grinding amount in the axial direction after sintering becomes problematic, and does not require the application of the present invention.

On the other hand, if the length of the cylindrical target material in the axial direction is too long, cracking and curving may frequently take place in the sintering step. From this point of view, in the present invention, the cylindrical target material of interest can be, for example, one having a length of 2000 mm or less in the axial direction.

The length of the cylindrical target material in the axial direction means a length of a line segment straightly connecting central points of end faces on one side and the other side in the axial direction to each other.

### (Bulk Resistivity)

The variation coefficient of the bulk resistivity in the axial direction on the outer peripheral surface of the cylindrical target material is 0.05 or less. For example, the production of the cylindrical target material according to a producing method as described later can provide such a low variation coefficient of the bulk resistivity in the axial direction.

If the variation coefficient of the bulk resistivity in the axial direction is higher than 0.05, it causes particles to bring about a problem of deterioration of film quality during sputtering.

In order to prevent the generation of particles during such sputtering more effectively, the variation coefficient of the bulk resistivity in the axial direction is preferably 0.05 or less, and more preferably 0.02 or less. The variation coefficient of the bulk resistivity in the axial direction is preferably as low as possible, and its excessive lower vale has no disadvantage. However, it may generally be 0.005 or more, and typically 0.01 or more.

The bulk resistivity is measured for the outer peripheral surface of the cylindrical target material, that is, a surface to be initially subjected to sputtering (usually a surface of a product whose outer surface is ground by a predetermined amount after sintering during the production), and the bulk resistivity on the outer peripheral surface of the cylindrical target material is measured based on a four probe method in accordance with JIS R1637.

The variation coefficient of the bulk resistivity in the axial direction is determined as follows: temporal one reference point is provided in the circumferential direction at a position of 10 mm from any one end in the axial direction. Fifteen points are measured in steps of 24° from that one point. Of the fifteen points, a point having the lowest resistance is regarded as a reference point for the end portion, and a straight line axially extending from the reference point along the surface is regarded as a measurement range of the resistance. The resistance is measured from the reference point for the end portion to a position of 10 mm from the opposite end portion at intervals of 50 mm. The same measurements are also carried out for three straight lines each shifted by 90° clockwise from the reference point for the end portion. Among the respective standard deviations of the four straight lines thus obtained, the standard deviation having the largest value is regarded as the maximum standard deviation, and the maximum standard deviation is divided by an average value of all the measured values for the four straight lines to calculate the variation coefficient of the bulk resistivity in the axial direction. That is, the variation coefficient of the bulk resistivity in the axial direction is calculated by the equation: (maximum standard deviation among standard deviations of four straight lines)/(average value of all measured values).

### (Relative Density)

A relative density of the cylindrical target material is preferably 99.0% or more. If the relative density of the cylindrical target material is lower, arcing would be caused during sputtering.

In the present invention, the “relative density” is represented by the equation: relative density=(measured density/theoretical density)×100(%). The theoretical density is a value of density calculated from the theoretical density of each oxide of each element excluding oxygen, in each constituent element of the formed body or the sintered body. For example, in the case of an IZO target, indium oxide (In₂O₃) and zinc oxide (ZnO) are used to calculate the theoretical density as the oxides of indium and zinc other than oxygen, among indium, zinc and oxygen which are the constituent elements. Here, conversion is performed from elemental analysis values (at % or % by mass) of indium and zinc in the sintered body to a mass ratio of indium oxide (In₂O₃) and zinc oxide (ZnO). For example, in the case of an IZO target with 90% by mass of indium oxide and 10% by mass of zinc oxide as a result of conversion, the theoretical density is calculated by the equation: {density of In₂O₃ (g/cm³)×90+density of ZnO (g/cm³)×10}/100 (g/cm³). The density of In₂O₃ is calculated as 7.18 g/cm³, the density of ZnO is calculated as 5.67 g/cm³, and the theoretical density is calculated as 7.028 (g/cm³). On the other hand, the measured density is a value obtained by dividing weight by volume. In the case of the sintered body, it is calculated by determining the volume according to the Archimedes method.

It should be noted that the relative density is based on the theoretical density when assuming that the cylindrical target material is a mixture of oxides of the metal elements contained, and a value of true density of the cylindrical target material of interest tends to be higher than the above theoretical density, so the relative density as used herein may exceed 100%.

### (Crystal Grain Size)

An average crystal grain size of the cylindrical target material is preferably 5 μm or less. If the average crystal grain size is more than 5 μm, it may become a generation source of particles. Therefore, the average crystal grain size of the cylindrical target material is more preferably 3 μm or less. The crystal grain size is determined from SEM photographs using the code method. Measurement points target four samples taken every 90° in the circumferential direction at the center in the axial direction, and the average crystal grain size can be calculated in each SEM photograph taken for those samples, using the number of all the grains on line segments drawn for measurement and lengths of the line segments.

### (Brazing Material)

The cylindrical sputtering target according to the present invention is obtained by joining the above cylindrical target material to the outer peripheral side of the metallic cylindrical substrate.

Here, the brazing material which is interposed between the cylindrical substrate and the cylindrical target material to join them can have a melting point of 200° C. or less. Such a brazing material is not particularly limited as long as it can be used for joining the cylindrical substrate to the cylindrical target material, including, specifically, In metal, In—Sn metal, or In alloy metal doped with a miner amount of a metal component, and the like.

### (Producing Method)

The cylindrical sputtering target including the cylindrical target material and the cylindrical substrate as stated above can be produced as follows, for example.

First, powder is prepared by mixing certain raw material powders according to the materials of the cylindrical target material to be produced, and a powder filling step is carried out, which fills a cylindrical forming space in a forming mold with the raw material powder.

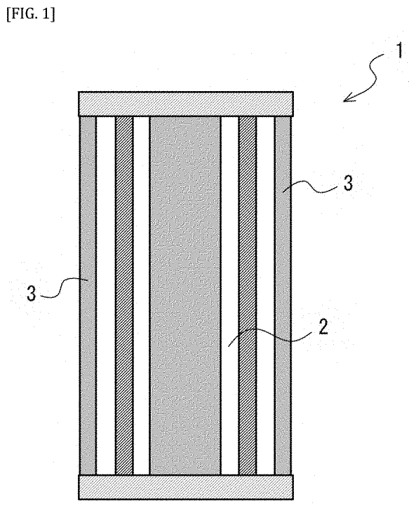

As the forming mold, a known mold can be used, and for example, a forming mold illustrated by the longitudinal cross-sectional view in FIG. 1 can be used.

In the powder filling step, the raw material powder is introduced from an upper end side of a forming space 2 into the forming space 2 in a state where a forming mold 1 stands vertically as shown in the FIGURE, and while being filled in the forming space 2, tapping vibrations in the up-down direction are provided, which lift up the forming mold 1 upward and drop down it, and on each occasion, abuts the forming mold 1 against the disposed surface.

According to this, the raw material powder filling the forming space 2 from the lower side is uniformly stacked in the circumferential direction of the forming space 2 in association with the tapping vibrations, so that a uniform amount of the raw material powder is filled in the forming space 2 in the circumferential and longitudinal directions.

Particularly, in this case, the tapping vibrations in the up-down direction are performed by abutting against the disposed surface at a frequency of five times or more while 1 kg of the raw material powder is filled in the forming space 2. If this frequency is less than 5 times, the raw material powder is accumulated in the longitudinal direction before the raw material powder is homogenized in the circumferential direction by the tapping vibrations, so that uniform filling of the raw material powder cannot be achieved. Therefore, the frequency of abutting against the disposed surface in the tapping vibrations in the up-down direction is 5 times or more, preferably 10 times or more, per 1 kg of an amount of the raw material powder to be filled. However, if the frequency is too large, it does not lead to further uniformity of the filling, so it can be 20 times or less.

Furthermore, in this case, the use of a sieve (not shown) disposed so as to cover the entire opening on the upper end side of the forming space 2 will allow the raw material powder to be uniformly charged from the entire sieve after temporarily stopping the flow of the raw material powder to be introduced into the forming space 2, so that the uniform amount of the raw material powder can be filled in the forming space 2. The mesh size of the sieve can be set to a size through which the raw material powder can pass, for example, from 2 to 10 times the size of the average grain size of the raw material powder.

The forming mold 1 in which the raw material powder has been filled in the forming space 2 is then disposed in a CIP device (not shown), and a forming step is carried out, which subjects the raw material powder in the forming space 2 to cold isostatic pressing. A pressure applied at this time can be, for example, from 100 MPa to 200 MPa.

This can allow the raw material powder in the forming space 2 to be compressed and pressurized from its periphery to provide a cylindrical formed body.

Here, in the powder filling step, the uniform amount of the raw material powder is filled in the forming space 2 in the circumferential direction and the longitudinal direction as described above and the filling irregularity is suppressed, so that the pressing force of the cold isostatic pressing will evenly act in the circumferential direction and in the longitudinal direction. As a result, the generation of curving in the cylindrical formed body is prevented.

In the forming step, the cold isostatic pressing is carried out by arranging a reinforcing member 3 for supporting the forming mold 1 from the outer peripheral side as shown in FIG. 1. As a result, even if the cylindrical target material having a longer length in the axial direction is produced, the reinforcing member 3 prevents unintended curving of the forming mold 1 during the cold isostatic pressing, so that the generation of curving of the cylindrical formed body thus obtained can be more effectively suppressed.

The shape of the reinforcing member 3 is not particularly limited as long as the reinforcing member 3 supports the forming mold 1 from its outer peripheral side and provides reinforcement against curving of the forming mold 1 during the cold isostatic pressing. For example, it can be a plurality of poles spaced apart from each other around an outer cylinder 5 of the forming mold 1 at certain intervals.

The cylindrical formed body thus obtained by subjecting the raw material powder to the cold isostatic pressing in the forming step has a curving amount of 1 mm or less. If the curving amount of the cylindrical formed body is more than 1 mm, an grinding amount have to vary largely in the axial direction in order to eliminate the curving, in grinding after sintering described below, so there is concern that the bulk resistivity of the outer periphery of the cylindrical target material will be non-uniform in the axial direction. Therefore, the curving amount of the cylindrical formed body is more preferably 0.5 mm or less.

The curving amount of the cylindrical formed body is measured using a straight edge and a gap gauge. The same applies to a curving amount of a cylindrical sintered body as described later.

After the forming step, a sintering step is carried out, which sinters at a temperature of 1300° C. to 1600° C. for 20 hours to 200 hours the cylindrical formed body whose dimensions are optionally adjusted by lathe processing or the like while placing the cylindrical formed body upright on the disposed surface, that is, placing the cylindrical formed body in a direction where the central axis is perpendicular to the disposed surface, to provide a cylindrical sintered body.

In general, the curving amount of the cylindrical sintered body is higher than that of the cylindrical formed body due to a difference in the sintering order and a difference in the shrinkage behavior depending on the heating state of the furnace through the heating and sintering in the sintering step. The producing method prevents the filling irregularity of the raw material powder and the curving of the forming mold 1 during the cold isostatic pressing as described above, and the curving amount of the cylindrical sintered body can be thus reduced. Specifically, the curving amount of the cylindrical sintered body is preferably 4 mm or less. A curving amount of the cylindrical sintered body of more than 4 mm may require significantly different curving amount in the axial direction when grinding the outer surface of the cylindrical sintered body, which may result in a decreased variation amount of the bulk resistivity on the outer peripheral surface of the cylindrical target material in the axial direction.

Subsequently, the outer surface of the cylindrical sintered body is ground by a known method such as mechanical grinding or chemical grinding to produce a cylindrical target material. In the grinding it is preferable to further grind the cylindrical sintered body by at least 0.1 mm in the thickness direction of the cylindrical sintered body on the basis of the surface where the curving amount is zero.

The cylindrical target material thus obtained is disposed on the outer peripheral side of the metal cylindrical substrate, and a space between the cylindrical target material and the cylindrical substrate, the brazing material or the like having a melting point of 200° C. or less as described above is poured in a molten state, and solidified by cooling the brazing material, whereby the cylindrical target material and the cylindrical substrate are joined to each other by the brazing material.

According to this, the cylindrical sputtering target can be produced.

### EXAMPLES

Next, the sputtering target according to present invention was experimentally conducted and its performance were confirmed as described below. However, the description herein is merely for the purpose of illustration and is not intended to be limited thereto.

Each raw material powder that mixed indium oxide powder and tin oxide at a weight ratio of 90:10 was filled in a forming space of a forming mold and subjected to cold isostatic pressing under a pressure of 150 MPa for 30 minutes to obtain a cylindrical formed body. Each cylindrical formed body thus obtained was heated in a furnace at a temperature of 1500° C., and maintained for 50 hours to sinter it, and then cooled. Each cylindrical sintered body thus obtained was further ground by 0.1 mm on the basis of the surface where the curving amount is zero by means of machining to produce a cylindrical target material having the length in the axial direction as shown in Table 1 according to each of Examples 1 to 4 and Comparative Examples 1 to 5.

TABLE 1

| | | | | Evaluation of Sintered Body and Target | | | | | | |
|---|---|---|---|---|---|---|---|---|---|---|
| | | | | | | | | | Variation | |
| | | | | Curving | | | | | Coefficient | |
| | Filling Method | | | of | Curving of | Length of | | | of Bulk | Sputtering |
| | Mesh | Number | | Formed | Sintered | Formed | Length of | Relative | Resistance in | Characteristics |
| | Size of | of | Reinforcement | Body | Body | Body | Target | Density | Longitudinal | Generation of |
| | Sieve | Tappingg | durig CIP | (mm) | (mm) | (mm) | (mm) | (%) | Direction | Particles |
| Example 1 | ◯ | ◯ | ◯ | 0.03 | 0.5 | 900 | 650 | 99.7 | 0.02 | 100 |
| Example 2 | ◯ | ◯ | ◯ | 0.04 | 1.5 | 1100 | 750 | 99.5 | 0.03 | 116 |
| Example 3 | ◯ | ◯ | ◯ | 0.05 | 2 | 1300 | 900 | 99.2 | 0.03 | 122 |
| Example 4 | ◯ | ◯ | ◯ | 0.05 | 3.5 | 1700 | 1350 | 99.0 | 0.03 | 111 |
| Comparative | X | ◯ | ◯ | 0.05 | 4.5 | 900 | 650 | 98.5 | 0.07 | 583 |
| Example 1 | | | | | | | | | | |
| Comparative | ◯ | X | ◯ | 0.05 | 5.8 | 1100 | 750 | 98.4 | 0.08 | 667 |
| Example 2 | | | | | | | | | | |
| Comparative | ◯ | ◯ | X | 1.5 | 6.5 | 1300 | 900 | 99.0 | 0.09 | 859 |
| Example 3 | | | | | | | | | | |
| Comparative | ◯ | Δ | ◯ | 0.05 | 5.5 | 1700 | 1350 | 98.9 | 0.07 | 732 |
| Example 4 | | | | | | | | | | |
| Comparative | Δ | ◯ | ◯ | 0.05 | 4.2 | 1100 | 750 | 98.8 | 0.06 | 584 |
| Example 5 | | | | | | | | | | |

Example 1 carried out, during the powder filling, filling of the raw material powder using the sieve having a mesh size that was 2 to 10 times the average grain diameter of the raw material powder and ten tapping vibrations per 1 kg of filling amount, as well as carried out the reinforcement of the forming mold using a plurality of pole-shaped reinforcing members as shown in FIG. 1. As shown in Table 1, each of Examples 2 to 4 was carried out in the same method as that of Example 1, with the exception that the length of the cylindrical target material in the axial direction was changed.

Comparative Example 1 was carried out in the same method as that of Example 1 with the exception that the filling of the raw material using the sieve was not performed. Comparative Example 2 was carried out in the same method as that of Example 2 with the exception that no tapping vibration was performed. Comparative Example 3 was carried out in the same method as that of Example 3 with the exception that no reinforcement during CIP was performed.

Comparative Example 4 was carried out in the same method as that of Example 4 with the exception that the number of tapping vibrations was less than 5. Comparative Example 5 was carried out in the same method as that of Example 1 with the exception that, in the filling of the raw material using the sieve, a sieve having a mesh size larger than 10 times the average grain diameter of the raw material powder was used.

In Table 1, the symbol “∘” of the mesh size of the sieve means that the mesh size was 10 times or less the average grain diameter of the raw material powder, and the symbol “Δ” means that the mesh size was more than 10 times the average grain diameter of the raw material powder, and the symbol “x” means that the sieve was not used. Moreover, the symbol “∘” of the number of tapping means that five or more tapping vibrations were carried out per 1 kg of filling amount, and the symbol “Δ” means that less than five tapping vibrations were carried out per 1 kg of filling amount, and the symbol “x” means that no tapping vibration was carried out. Further, the symbol “∘” of reinforcement during CIP means that the reinforcing member was used, and the symbol “x” means that no reinforcing member was used.

The ratio of the size of the mesh size of the sieve to the average grain diameter of the raw material powder may not be strictly determined because the average grain diameters of the raw material powders may be slightly different in the respective examples. However, in general, for the symbol “∘”, three types of sieves having mesh sizes that were approximately from 2 to 5 times, from 5 to 8 times, and from 8 to 10 times the average grain diameter were used, and for the symbol “Δ”, one sieve having a mesh size that was approximately from 11 to 15 times the average grain diameter was used.

For each of Examples 1 to 4 and Comparative Examples 1 to 5, the curving amount of each of the cylindrical formed body and the cylindrical sintered body was measured according to the method as stated above, and the results are as shown in Table 1.

In each of Comparative Examples 1 to 5, the curving of the sintered body was larger than that of each of Examples 1 to 4. In particular, with regard to Comparative Example 4, the curving of the sintered body could not be effectively suppressed when the number of tapping was two or four. Moreover, with regard to Comparative Example 5, the sieve having the excessively large mesh size did not provide sufficient suppression of the curving of the sintered body.

The bulk resistivity of the outer peripheral surface of each of the cylindrical target materials of Examples 1 to 4 and Comparative Examples 1 to 5 was measured using a resistivity measuring device (model number: Σ5+) from NPS, INC, and a variation coefficient of the bulk resistivity in the axial direction was determined. The results are also shown in Table 1.

Each of the cylindrical target materials of Examples 1 to 4 and Comparative Examples 1 to 5 was joined to the outer peripheral side of the cylindrical substrate via the brazing material, and using the resulting sputtering target, sputtering was carried out under conditions of an input power of 4.0 kW/m, an Ar gas flow rate of 20 Sccm and a sputtering time of 24 hours. As a result, when the number of particles of Example 1 was 100 based on the number of particles of Example 1, the number of particles was 150 or less for Examples 2 to 4, and the number of particles was from 500 to 900 for Comparative Examples.

The cylindrical target materials of IZO and IGZO were also produced and tested in substantially the same procedures as described above to obtain substantially the same results. Therefore, according to the present invention, it was found that for both cylindrical target materials of IZO and IGZO, the curving of the formed body or the sintered body could be suppressed, and the uniform resistance characteristics in the axial direction could be achieved.

### DESCRIPTION OF REFERENCE NUMERALS

1 forming mold
2 forming space
3 reinforcing member

1. A cylindrical sputtering target, comprising: a metallic cylindrical substrate; and a ceramic cylindrical target material joined to an outer peripheral side of the cylindrical substrate and integrally formed so as to have a length of 750 mm or more in an axial direction, wherein a variation coefficient of a bulk resistivity in an axial direction is 0.05 or less on an outer peripheral surface of the cylindrical target material.

2. The cylindrical sputtering target according to claim 1, wherein the cylindrical target material has a relative density of 99.0% or more relative to theoretical density.

3. The cylindrical sputtering target according to claim 1, wherein the cylindrical target material is ITO, IZO, or IGZO.

4. The cylindrical sputtering target according to claim 1, wherein the cylindrical substrate and the cylindrical target material are joined by a brazing material having a melting point of 200° C. or less.

5. A method for producing a cylindrical sputtering target comprising a metallic cylindrical substrate and a ceramic cylindrical target material joined to an outer peripheral side of the cylindrical substrate and integrally formed so as to have an axial length of 750 mm or more, the method comprising:
a powder filling step of filling a cylindrical forming space in a forming mold with raw material powder;
a forming step, after the powder filling step, of subjecting the raw material powder in the forming space to cold isostatic pressing to form a cylindrical formed body; and
a sintering step, after the forming step, of sintering the cylindrical formed body by heating to provide a cylindrical sintered body,
wherein the powder filling step comprises providing tapping vibrations in an up-down direction for dropping down the forming mold to abut against a disposed surface with the forming mold, while an opening portion on an upper end side of the forming space is provided with a sieve so as to cover the opening portion and the raw material powder is filled in the forming space through the sieve, and the raw material powder is filled in the forming space while carrying out at least five tapping vibrations per 1 kg of an amount of the raw material powder filled; and
wherein the forming step comprises performing the cold isostatic pressing while disposing a reinforcing member for supporting the forming mold from its outer peripheral side.

6. The method according to claim 5, wherein the cylindrical formed body has a curving amount of 1 mm or less.

7. The method according to claim 5, wherein the cylindrical formed body has a curving amount of 4 mm or less.
